(19) United States
(12) Patent Application Publication
(10) Pub. No.: US 2013/0277333 A1
(43) Pub. Date: Oct. 24, 2013

(54) PLASMA PROCESSING USING RF RETURN PATH VARIABLE IMPEDANCE CONTROLLER WITH TWO-DIMENSIONAL TUNING SPACE

(71) Applicant: APPLIED MATERIALS, INC., Santa Clara, CA (US)

(72) Inventors: Nipun Misra, San Jose, CA (US); Kartik Ramaswamy, San Jose, CA (US); Yang Yang, Sunnyvale, CA (US); Douglas A. Buchberger, JR., Livermore, CA (US); James D. Carducci, Sunnyvale, CA (US); Lawrence Wong, Fremont, CA (US); Shane C. Nevil, Livermore, CA (US); Shahid Rauf, Pleasanton, CA (US); Kenneth S. Collins, San Jose, CA (US)

(21) Appl. No.: 13/842,287

(22) Filed: Mar. 15, 2013

Related U.S. Application Data
(60) Provisional application No. 61/637,558, filed on Apr. 24, 2012.

(51) Int. Cl. C23F 1/08; C23C 16/505

(52) U.S. Cl. CPC C23F 1/08; C23C 16/505
USPC 216/61; 118/723 E; 118/696; 427/569; 156/345.24; 216/67

(57) ABSTRACT

In a plasma reactor having a driven electrode and a counter electrode, an impedance controller connected between the counter electrode and ground includes both series sand parallel variable impedance elements that facilitate two-dimensional movement of a ground path input impedance in a complex impedance space to control spatial distribution of a plasma process parameter.

### CROSS-REFERENCE TO RELATED APPLICATIONS

This application claims the benefit of U.S. Provisional Application Ser. No. 61/637,553 filed Apr. 24, 2012 entitled PLASMA PROCESSING USING RF RETURN PATH VARIABLE IMPEDANCE CONTROLLER WITH TWO-DIMENSIONAL TUNING SPACE, by Nipun Misra, et al.

### BACKGROUND

Plasma enhanced reactive ion etch (PERIE) reactors, for processing workplaces such as semiconductor wafers, employ various techniques tor improving uniformity of etch rate across the surface of the workplace. Typically, radial distribution of etch rate is controlled so as to improve uniformity by controlling gas flow rates in different radial gas injection zones of the reactor, or by controlling magnetic fields in the reactor chamber, for example. In some cases, the RF plasma source power applicator may be divided into radially inner and outer portions, and radial distribution of etch rate further adjusted by controlling the RF power levels applied to the inner and outer zones. Although various combinations of such techniques have enjoyed some success in improving process uniformity, as wafer diameter increases and semiconductor device geometries and critical dimensions continue to be reduced to improve device performance, greater improvements in process uniformity are required. There is a need for improved control over plasma process uniformity and in particular there is a need for improving uniformity of process rate, such as radial distribution of etch rate or of deposition rate.

### SUMMARY

A plasma reactor with a pair of counter electrodes has an RF power generator coupled to one of the electrodes and an impedance controller having a pair of terminals connected between the other electrode and ground. The impedance controller includes a load impedance element, a variable series impedance element connected in series between the first terminal and the load impedance element, and a variable parallel impedance element connected across one of (a) the first and second terminals, (b) the load impedance element, the parallel impedance element having a variable parallel impedance. A process controller is connected to each one of the series and parallel variable impedance elements to vary the variable series impedance and the variable parallel impedance, and is adapted to set an input impedance across the first and second terminals to a complex value corresponding to a desired spatial distribution of a plasma process parameter.

A method of controlling a plasma process parameter in processing a workpiece in a chamber of a plasma reactor includes providing a pair of RF power applicators disposed, respectively, at a ceiling and at a workpiece support of the plasma reactor, placing a production workpiece in the chamber and applying RF power to ore of the RF power applicators, providing a ground return path through an impedance controller having a parallel impedance element and a series impedance element, and changing the impedances of the parallel and series impedance elements so as to move an input impedance of the impedance controller to a location in a two-dimensional complex impedance space at which a desired distribution of a plasma process parameter across a surface of the workpiece is realized.

In one aspect, the plasma process parameter is a spatial distribution of a plasma process rate, the plasma process rate being one of an etch rate or a deposition rate.

### BRIEF DESCRIPTION OF THE DRAWINGS

So that the manner in which the exemplary embodiments of the present invention are attained and can be understood in detail, a more particular description of the invention, briefly summarized above, may he had by reference to the embodiments thereof which are illustrated in the appended drawings. It is to be appreciated that certain well known processes are not discussed herein in order to not obscure the invention,

FIG. 1 is a simplified diagram of a plasma reactor system embodying the present invention.

FIG. 2 is a simplified block diagram of a first type of impedance controller for the system of FIG. 1 capable of varying input impedance within a two-dimensional impedance space.

FIGS. 2A, 2B, 2C and 2D are simplified block

diagrams of different embodiments of the impedance controller of FIG. 2.

FIG. 3 is a simplified block diagram of a second type of impedance controller for the system of FIG. 1 capable of varying input impedance within a two-dimensional complex impedance space.

FIGS. 3A, 3B, 3C and 3D are simplified block diagrams of different embodiments of the impedance controller of FIG. 3.

FIG. 4 is a graph depicting movement of input impedance by the impedance controller of FIG. 2 or FIG. 3 across a complex impedance space of normalized reflection coefficient polar coordinates.

FIG. 5 is a block flow diagram depicting a method of operating the system of FIG. 1 including input impedance variation as depicted in FIG. 4.

FIG. 6 is a table depicting an example of information stored in a memory employed in the method of FIG. 5.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

The present invention concerns a plasma reactor having a capacitively coupled plasma source in the form of an electrode driven at an RF frequency by an RF power generator, and a counter electrode providing a ground return path for the RF power. An impedance controller governs the impedance through the ground return path. It is a discovery of the invention that the distribution of plasma ion density distribution at the workpiece surface may foe controlled by two-dimensional motion of the RF ground return path impedance across a two-dimensional complex impedance space. While not subscribing to any particular theory, it is believed the ability to direct changes in both the real and imaginary components of impedance enables the user to move the ground return path impedance to any point within a two-dimensional complex impedance space. Such control is realized by providing in the impedance controller a parallel variable impedance element connected in parallel with an input port of the impedance controller, and series variable impedance element connected in series with the input port. Independent variation of the parallel and series impedance elements facilitates movement of the input impedance to any desired point in a two-dimensional complex impedance space.

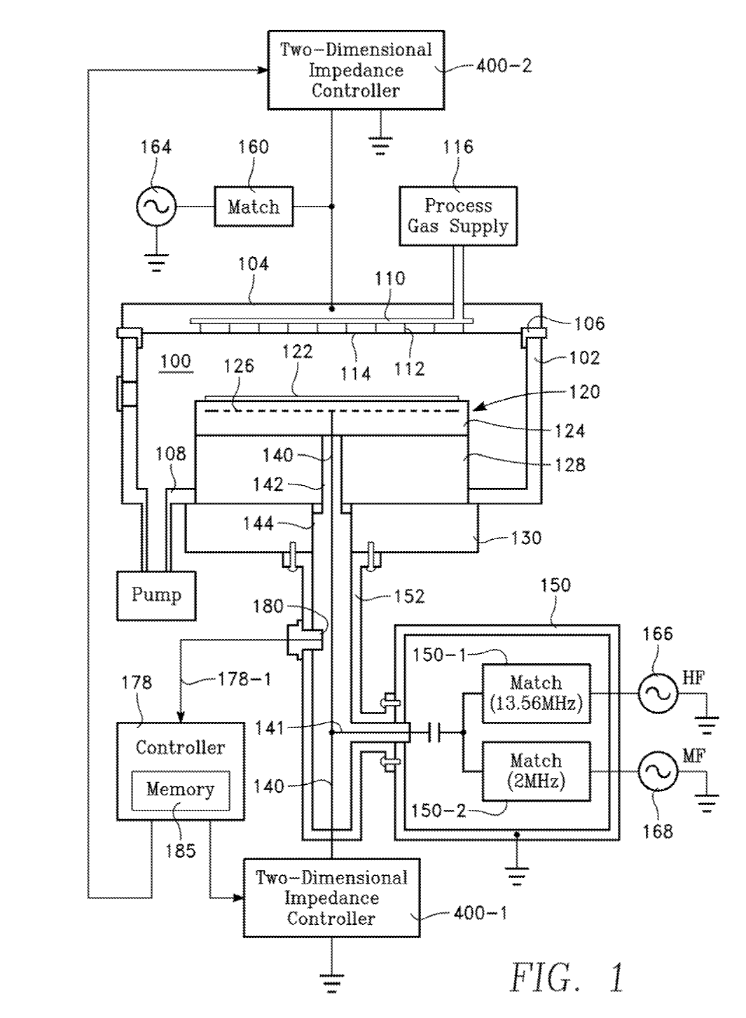

Referring to FIG. 1, a plasma reactor system in accordance with one embodiment includes a reactor chamber 100 enclosed by a metallic cylindrical side wall 102 supporting a ceiling electrode 104, the wall 102 and electrode 104 being separated by an insulating ring 106. The chamber 100 may further foe defined by a floor 108. The ceiling electrode 104 may optionally include an internal gas manifold 110 and plural gas injection ports 112 on its interior surface 114. A process gas supply 116 furnishes process gas to the manifold 110. A cathode or workpiece support pedestal 120 for supporting a workpiece 122 may be an electrostatic chuck (ESC) that includes a ceramic puck 124, an ESC electrode 126 within the puck 124, an aluminum base 128 and an aluminum utilities plate 130. Electrical connection to the ESC electrode 126 is provided by an RF feed conductor 140 extending through the center of the utilities plate 130, the base 128 and the puck 124. The RF feed conductor 140 is insulated from the metal base 128 by a coaxial insulator 142. The RF feed conductor 140 is insulated from the metal plate 130 by a coaxial insulator 144. As indicated in FIG. 1, the RF feed conductor 140 and the coaxial insulator 144 extend axialiy through the bottom of the plate 130, and then in a radial direction toward an bias impedance match box 150. The portion of the coaxial insulator 144 extending below the plate 130 is surrounded by a coaxial metal shield 152. A radial RF feed conductor 141 extends from the impedance match box 150 to the axial RF feed conductor 140.

RF source power, which may be of a VHF frequency, is applied to the ceiling electrode 104 through an RF impedance match 160 by an RF power generator 164. HF and MF (or LF) bias power is applied to the RF feed conductor 141 through the bias impedance match box 150 by an HF generator 166 (e.g., of a frequency of 13.56 MHz) and an MF generator 168 (e.g., of a frequency of 2 MHz). The bias impedance match box 150 may include an HF impedance match component 150-1 and an MF impedance match component 150-2.

An RF ground return path for the RF source power from the ceiling electrode 104 is provided through the ESC electrode 126 by coupling the RF feed conductor 140 to ground through a ground return path impedance controller 400-1. The impedance controller 400-1 is capable of varying its input impedance in a two-dimensional manner across a two-dimensional complex impedance space. In one embodiment, a filter circuit (not shown), or the impedance controller 400-1 itself, provides a high impedance at the frequencies of the bias power generators 166, 168, in order to avoid shorting the bias power generators 166, 168 to ground through the RF feed conductor 140.

An RF ground return path for the RF bias power from the ESC electrode is provided through the ceiling electrode 104 by coupling the ceiling electrode 104 to ground through a ground return path impedance controller 400-2. The impedance controller 400-2 is capable of varying its input impedance in a two-dimensional manner across a two-dimensional complex impedance space. In one embodiment, a filter circuit (not shown), or the impedance controller 400-2 itself, provides a high impedance at the frequency of the RF source power generator 164, in order to avoid shorting the source power generator 164 to ground through the ceiling electrode 104.

The two dimensional movement in complex impedance space of the input impedance of each impedance controller 400-1 and 400-2 is essential to fulfill a desired plasma process rate distribution (e.g., etch rate or deposition rate distribution) under a wide variety of conditions. For example, a process recipe may call for different levels of applied RF power, chamber pressure, process gas flow rates, and the like, and each change may require that the input impedance be moved to a different location in the impedance space in order to realize a desired process rate distribution across the workplace surface. Such adjustment further enables the desired plasma process rate distribution to be met for different reactor chamber designs, involving different resonances. The two-dimensional movement of input impedance in a complex impedance space is facilitated by the provision of a network of both parallel and. series variable impedance elements and a load impedance element, in each impedance controller 400-1 and 400-2.

The first and second variable impedance controllers 400-1 and 400-2 have networks of the same general structure, which structure will now be described for both the first and second variable impedance controllers 400-1 and 400-2.

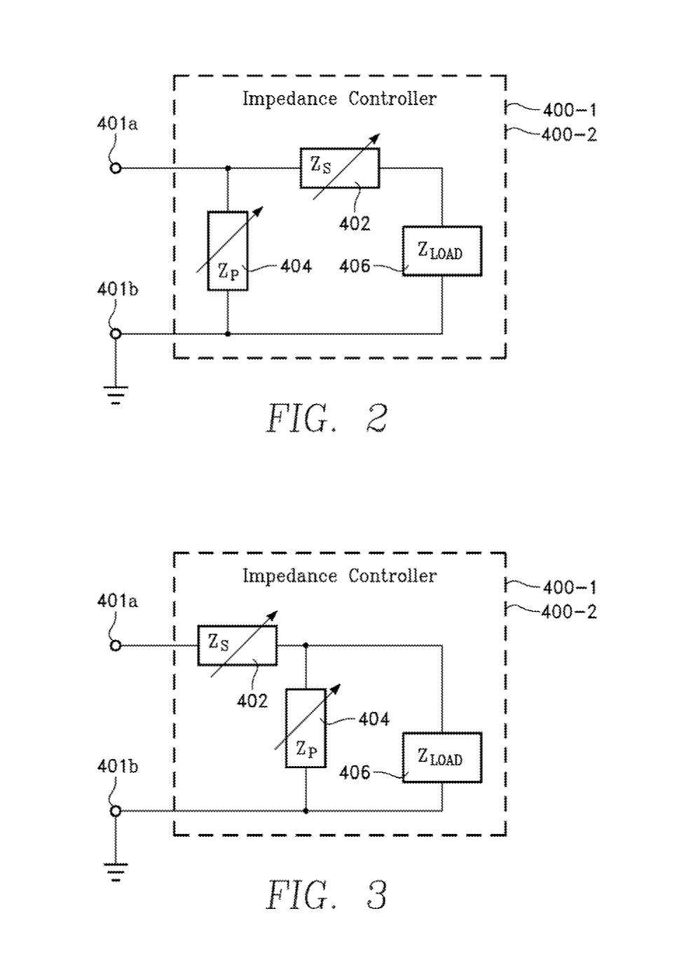

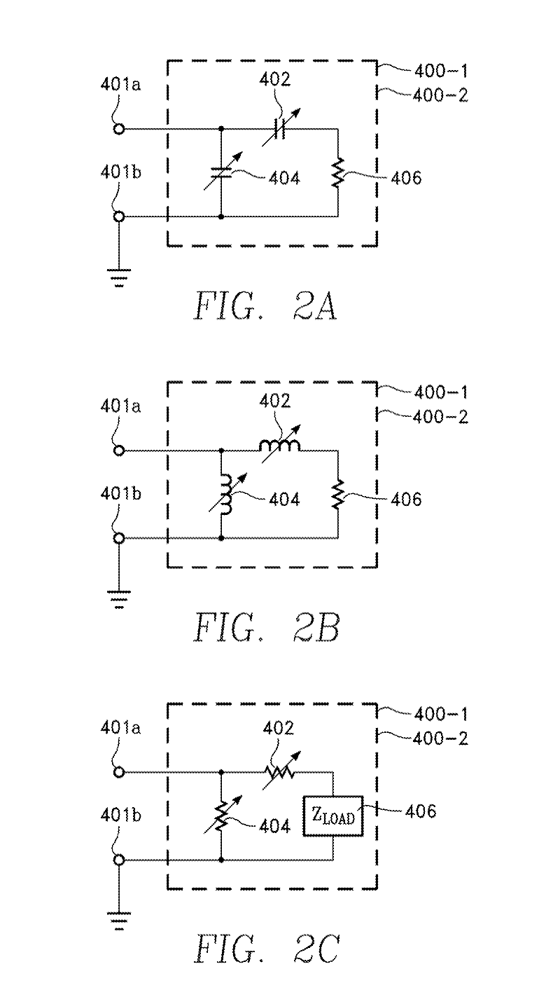

FIG. 2 depicts a first type structure which may be adopted into either one or both of the variable impedance controllers 400-1 and 400-2. The structure of FIG, 2 is a network that includes a pair of terminals 401a, and 401b, a series variable impedance element 402, a parallel variable impedance element 404 and a load impedance element 406. The terminal 401a is connected to receive the RF power being returned to ground (e.g., from one of the counter electrodes) and the terminal 401b is connected to RF ground. The parallel impedance element 404 is connected across the two terminals 401a, 401b. The series impedance element 402 is connected in series with the load impedance element 406, their series combination being connected in parallel with the parallel impedance element 404. Generally, the load impedance 406 is a fixed element, although in alternative embodiments it may have a variable impedance.

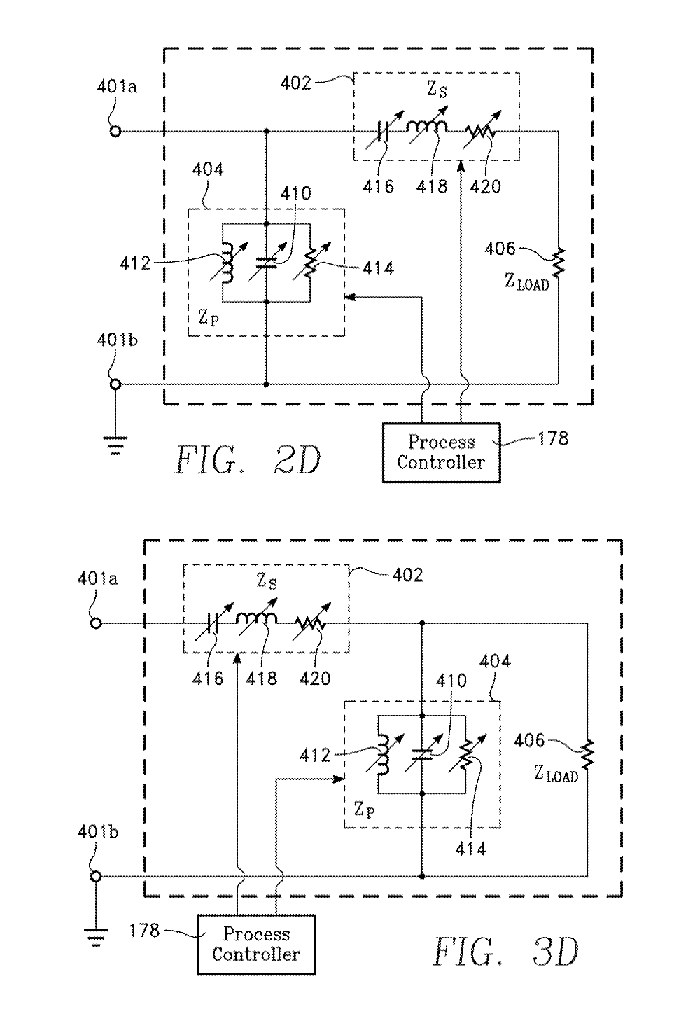

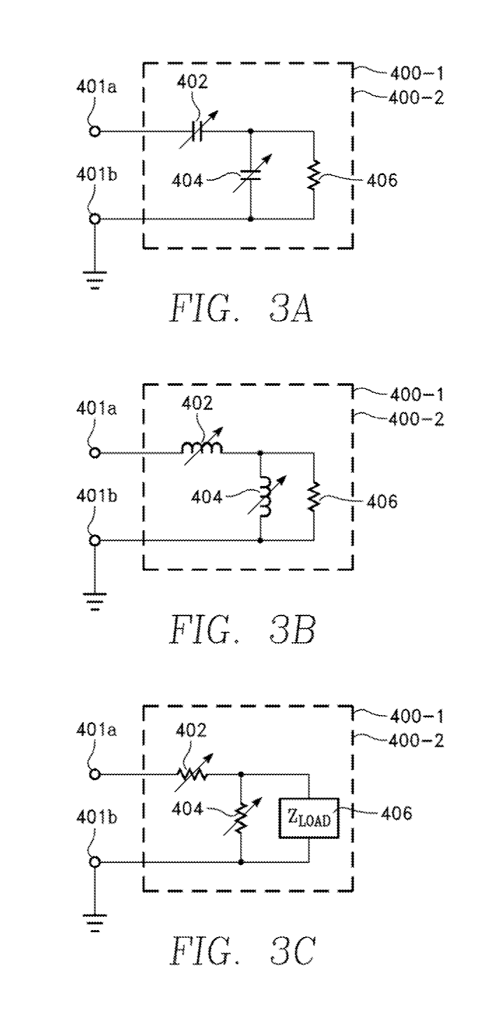

FIG. 3 depicts a second type of structure which may be adopted into either one or both of the of the variable impedance controllers 400-1 and 400-2, and may be considered as a rearrangement of the elements of FIG. 2. In FIG. 3, the series impedance element 402 is connected in series with the terminal 401a, while the parallel impedance element 404 and the load impedance element 406 are connected in parallel with each other, their parallel combination being connected in series between the series impedance element and the terminal 401b.

FIGS. 2A through 2D depict different embodiments of the first type of structure depicted in FIG. 2. In the embodiment of FIG. 2A, the series and parallel variable impedance elements 402, 404 are each variable capacitors, while the load impedance element 406 is a resistor. In the embodiment of FIG. 2B, the series and parallel variable impedance elements 402, 404 are each variable inductors, while the load impedance element 406 is a resistor. In the embodiment of FIG. 2C, the series and parallel variable impedance elements 402, 404 are each variable resistors, while the load impedance element 406 is a reactance element such as a capacitor or an inductor. In the embodiment of FIG. 2D, the parallel variable impedance element 404 includes plural individual variable impedance elements, which may include any or all of the following: a variable capacitor 410, a variable inductor 412 and a variable resistor 414. Furthermore in FIG. 2D, the series parallel variable impedance element 402 includes plural individual variable impedance elements, which may include any or ail of the following: a variable capacitor 416, a variable inductor 418 and a variable resistor 420. As indicated in the drawings of FIGS. 2, 2A, 28, 2C and 2D, each one of the variable capacitors, variable inductors and variable resistors is individually controlled or varied by a process controller 178.

FIGS. 3A through 3D depict different embodiments of the type of structure of FIG. 3. In the embodiment of FIG. 3A, the series and parallel variable impedance elements 402, 404 are each variable capacitors, while the load impedance element 406 is a resistor. In the embodiment of FIG. 3B, the series and parallel variable impedance elements 402, 404 are each variable inductors, while the load impedance element 406 is a resistor. In the embodiment of FIG. 3C, the series and parallel variable impedance elements 402, 404 are each variable resistors, while the load impedance element 406 is a reactance element such as a capacitor or an inductor. In the embodiment of FIG. 3D, the parallel variable impedance element 404 includes plural individual variable impedance elements, which may include any or ail of the following: a variable capacitor 410, a variable inductor 412 and a variable resistor 414. Furthermore in FIG. 3D, the series parallel variable impedance element 402 includes plural individual variable impedance elements, which may include any or ail of the following: a variable capacitor 416, a variable inductor 418 and a variable resistor 420. As indicated in the drawings of FIGS. 3, 3A, 3B, 3C and 3D, each one of the variable capacitors, variable inductors and variable resistors is individually controlled or varied by a process controller 178.

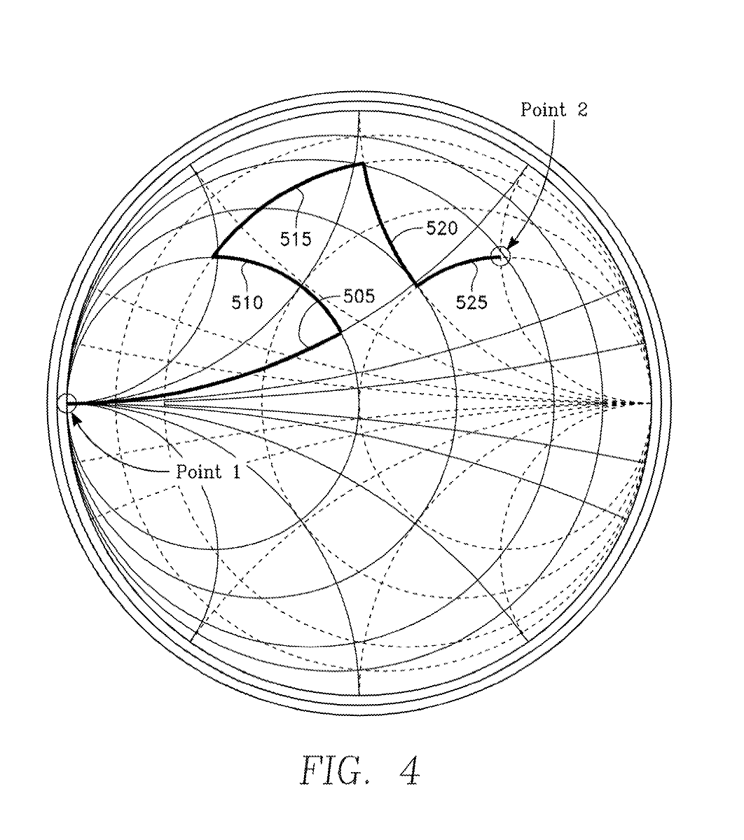

FIG. 4 is a graphical depiction of movement of input impedance measured across the impedance controller terminals 401a and 401b, in a complex two-dimensional space of normalized reflection coefficient polar coordinates, typically referred to as a Smith chart. While the coordinates of the two-dimensional space of FIG. 4 are normalized reflection coefficients, and while the graph of FIG. 4 depicts both impedance and admittance, the space is referred to herein as a complex impedance space. The center of the space is a point at which the reflection coefficient is zero (no reflected power), and the space is bounded by an outer circle at which the reflection coefficient is unity (all power is reflected). The impedance real part corresponds to the horizontal axis and the impedance imaginary part corresponds to the vertical axis. Movement of the input impedance in the two-dimensional space of FIG. 4 may be achieved, for example, by controlling the variable impedance elements of the impedance controller of FIG. 2D. The graph of FIG. 4 includes circles of constant resistance (dashed line circles), circles of constant conductance (solid line circles), curves of constant reactance (dashed line curves or arcs) and curves of constant susceptance (solid line curves or arcs). Varying the capacitor 416 or inductor 418 in the series impedance element 402 moves the input impedance around a circle of constant resistance. Varying the resistor 420 in the series impedance element 402 moves the input impedance along a curve of constant reactance. Varying the capacitor 410 or inductor 412 in the parallel impedance element 404 moves the input impedance around a circle of constant conductance. Varying the resistor 414 in the parallel impedance element 404 moves the input impedance along a curve of constant susceptance. Such movements may be combined to move the input impedance in a two-dimensional manner to all or most regions of the complex impedance space depicted in the graph of FIG. 4. This wide range of movement enables each impedance controller 400-1 and 400-2 to meet a very wide range of process conditions while enabling the process controller 178 to realize a desired plasma process rate distribution.

As an illustrative example, the input impedance (measured across the terminals 401a and 401b) may foe moved from an initial location at Point 1 in the graph of PIG, 4 to Point 2 in the graph of FIG. 4 by the following procedure; First, the impedance is moved from Point 1 along a curve 505 of constant susceptance, until meeting a circle 510 of constant conductance, by varying the variable resistor 412 of the parallel impedance element 404 of FIG. 2D. Next, the impedance is moved counter-clockwise along the circle 510 of constant conductance, until meeting a circle 515 of constant resistance, by varying the variable inductor 412 of the parallel impedance element 404 of FIG. 2D. Then, the impedance is moved along the circle 515 of constant resistance, until meeting a carve 520 of constant reactance, by varying the variable inductor 418 in the series impedance element 402 of FIG. 2D. Thereafter, the impedance is moved along the curve 520 of constant reactance, until meeting a circle 525 of constant resistance, by varying the variable resistor 420 in the series impedance element 402. Finally, the impedance is moved along the circle 525 of constant resistance, until reaching Point 2, by varying the variable inductor 418 in the series impedance element of FIG. 2D. Any other combination of such changes may be employed to obtain a desired movement of the input impedance, and this feature is not confined to the foregoing illustrative example.

The process controller 178 controls either one or both of the impedance controllers 400-1 and 400-2 to obtain a desired spatial distribution across the workpiece surface of a plasma process rate (e.g., an etch rate or a deposition rate). It is our discovery that moving the input impedance of an impedance controller (such as one of the impedance controllers 400-1 and 400-2) to different locations in the complex 2-dimensional impedance space represented in FIG. 4 produces different process rate distributions. This behavior enables the process controller 178 to control the plasma process rate distribution by controlling input impedance in the complex 2-dimensional impedance space. Such a control method may be referred to as 2-dimensional impedance control of process rate distribution. In such a method, the process controller 178 is provided with an observation of process rate distribution, and uses that observation to find the input impedance that provides the desired process rate distribution. The process rate distribution can be observed, for example, by measuring etch depth distribution or deposition thickness distribution on a test wafer after performing a plasma process on the test wafer. Alternatively, the process rate distribution can be observed by employing a sensor or sensing system that can observe or infer process rate distribution in real time during processing of a production workpiece. A generalized method of operating the process controller 178 to carry out the 2-dimensional impedance control of process rate distribution will now be described for the case in which the process controller 178 controls one of the impedance controllers 400-1 and 400-2, namely the impedance controller 400-1. However, the same method may be employed to control either impedance controller 400-1 or 400-2.

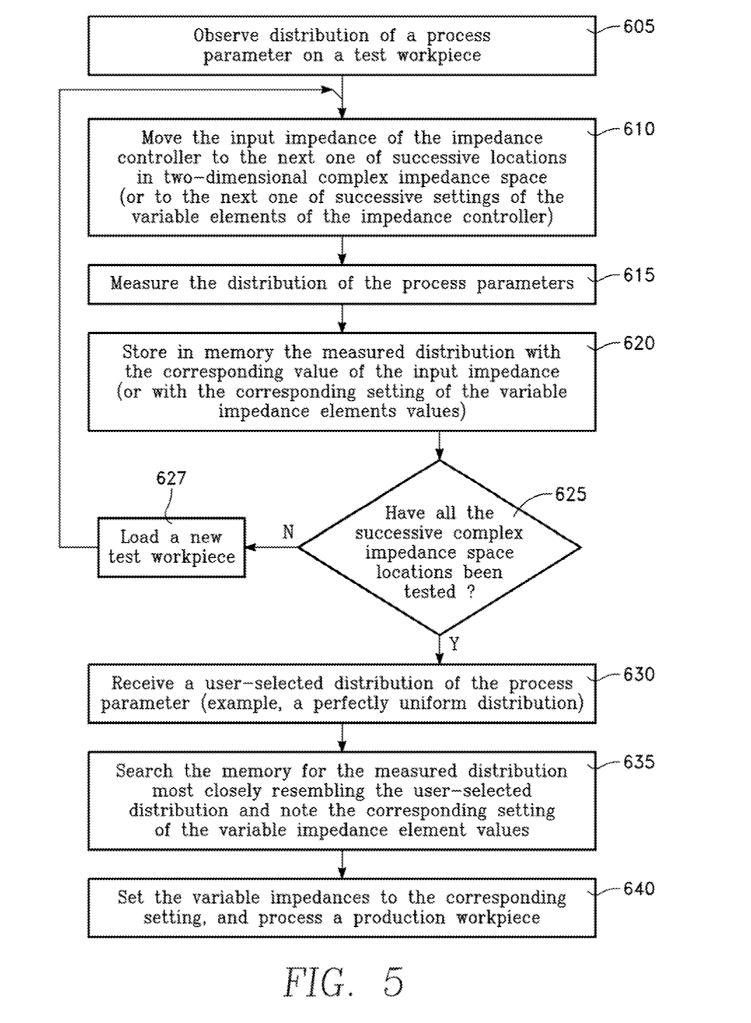

In general, the process controller 178 searches for an input impedance at which the measured process rate distribution closely matches a user-selected process rate distribution (e.g., etch rate distribution or deposition rate distribution) across the surface of the workpiece 122 shown in FIG. 1. For example, the desired process rate distribution may be a perfectly uniform distribution. For this purpose, the plasma process rate distribution is observed for a current test workpiece (block 605 of FIG. 5) by observing an etch depth distribution (for an etch process) or a deposition thickness distribution (for a deposition process) on the test wafer upon completion of a specified plasma process. The controller 178 changes various variable capacitors, inductors or resistors in the parallel and. series impedance elements 402, 404 of the impedance controller 400-1 to set the input impedance of the impedance controller 400-1 to successive set of locations in the 2-dimensional complex impedance space (block 610 of FIG. 5), corresponding to successive trial settings of the variable impedance elements 402 and 404. The set of locations may be distributed throughout the 2-dimensional complex impedance space, for example.

For each location, the process controller 178 notes the setting of each of the variable impedance elements 402, 404 and obtains a measurement (or image) of the process rate distribution across the surface of the current test workpiece (block 615 of FIG. 5). The measurement may be an etch depth distribution or a deposition depth distribution obtained upon completion of a specified plasma process. The current setting of the variable impedance elements 402 and 404 and the corresponding measured process rate distribution are stored in a memory 185 (block 620). Until all impedance values have been visited (NO branch of block 625), a new test workpiece replaces the previous one (block 627) and the process controller 178 repeats the steps of blocks 610, 615, 620 and 627 until all the input impedance values in the predetermined set have been explored (YES branch of block 625).

Thereafter, the process controller 178 governs processing of a production workplace. First, the controller 178 receives a user-defined or desired plasma process rate distribution which is desired (block 630). For example, the desired distribution may be a center-high distribution or a center-low distribution or a perfectly uniform distribution. The process controller 178 searches the memory 185 for a measured process rate distribution that most closely matches the desired distribution, and fetches from the memory 185 the corresponding setting of the variable impedance elements 402 and 404 (block 635). The process controller 178 then sets the variable impedance elements 402 and 404 in accordance with the corresponding settings (block 640), and a production workpiece is processed in the reactor.

During processing of the production workpiece, instabilities in plasma conditions may be compensated by controlling the impedance controller 400-1 (and/or the impedance controller 400-2) in a feedback control loop employing an RF sensor or probe. In one example, an RF probe 180 (depicted in FIG. 1) that senses RF current or RF voltage is tuned to sense RF frequencies in a narrow frequency band of interest. For example, the band may be centered at the frequency of the RF source power generator 160, or the band may be centered at the frequency of one of the RF bias power generators 166 or 168, for example. The probe 180 may be located so as to sense RF current or voltage at the ESC 126 (as depicted in FIG. 1). Alternatively, the probe may be disposed so as to send RF current or RF voltage at the ceiling electrode 104. The process controller 178 has a control input 178-1 that is connected to the output of the RF probe 180. The process controller 178 is programmed to compensate for fluctuations in the sensed RF voltage or current measured by the RF probe 180, so as to reduce the fluctuations, in the manner of a feedback control loop. In one example, the process controller 178 may be programmed to respond to a fluctuation in the output of the RF probe 180 by performing a trial-and-error procedure. In such a procedure, the process controller 178 makes a succession of trial incremental changes in different ones of the variable impedance elements of the impedance controller 400-1 (or 400-2). The process controller 178 determines which incremental change resulted in the greatest reduction in the sensed fluctuation, and repeats the same incremental change, until the fluctuation has been minimized.

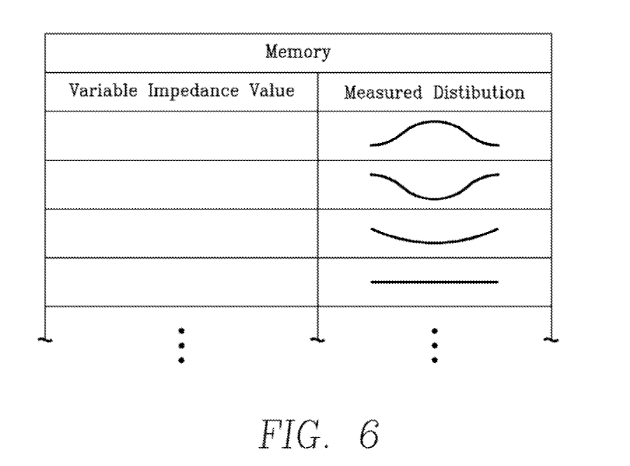

FIG. 6 is a table depicting an example of the contents of the memory 185. Each row includes a pair of memory locations storing, respectively: (A) a value of the input impedance and (B) a corresponding measurement (or image) of the corresponding plasma process rate distribution. Alternatively, the value of the input impedance may be represented, as a listing of the setting of each of the variable impedance elements, or as the coordinates of the input impedance in the graph of FIG. 4. In the example of FIG. 6, each measured distribution is represented, by an image of the radial distribution of process rate, some being center high, and others being edge high, and still others approaching a uniform distribution. Alternatively, if the desired distribution is uniform, then the memory 185 stores a measure of the uniformity of the distribution (e.g., its variance) rather than an image of the distribution.

While the foregoing is directed to embodiments of the present invention, other and. further embodiments of the invention may be devised without departing from the basic scope thereof, and the scope thereof is determined by the claims that follow.

1. A plasma reactor comprising:
a reactor chamber comprising a ceiling and a side wall, workpiece support inside said chamber facing said ceiling, a pair of RF power applicators disposed, respectively, at said ceiling and at said workpiece support;
an RF power generator coupled to one of said RF power applicators and having a return terminal coupled to ground;
an impedance controller having a first terminal connected to the other one of said RF power applicators and a second terminal connected to ground, said impedance controller comprising:
a load impedance element;
a series impedance element connected in series between said first terminal and said load impedance element, said load impedance element being connected in series between said series impedance element and said second terminal, said series impedance element having a variable series impedance;
a parallel impedance element connected across one of (a) said first and second terminals, (b) said load impedance element, said parallel impedance element having a variable parallel impedance; and
a process controller connected to each one of said series and parallel variable impedance elements to vary said variable series impedance and said variable parallel impedance, and adapted to set an input impedance across said first and second terminals to a complex value corresponding to a desired spatial distribution of a plasma process parameter.

2. The plasma reactor of claim 1 wherein said parallel and series impedance elements comprise variable reactance elements having variable reactances controlled by said controller, and wherein said load impedance comprises a fixed resistor.

3. The plasma reactor of claim 2 wherein said variable reactance elements comprise variable capacitors and said load impedance comprises a resistor.

4. The plasma reactor of claim 2 wherein said variable reactance elements comprise variable inductors and said load impedance comprises a resistor.

5. The plasma reactor of claim 2 wherein said parallel impedance element comprises at least two of (a) a variable capacitor controlled by said controller, (b) a variable inductor controlled by said controller, (c) a variable resistor controlled by said controller.

6. The plasma reactor of claim 2 wherein said series impedance element comprises at least two of (a) a variable capacitor controlled by said controller, (b) a variable inductor controlled by said controller, (c) a variable resistor controlled by said controller.

7. The plasma reactor of claim 1 wherein said parallel and series impedance elements comprise variable resistors controlled by said controller, and wherein said load impedance comprises a reactive impedance element.

8. The plasma reactor of claim 1 further comprising a memory storing sets of values of said variable parallel and series impedances, and a measurement of a plasma process parameter for each one of said sets of values of said variable parallel and series impedances, wherein said controller is adapted to search said memory for a set of said values corresponding to a measurement of the plasma process parameter most closely matching a user-designated measurement.

9. The plasma reactor of claim 1 further comprising:
an RF sensor disposed near one of said electrodes and adapted to sense RF voltage or RF current;
said process controller having an input connected to an output of said RF sensor, said process controller being adapted to vary said input impedance across said first and second terminals so as to oppose fluctuations in an output signal from said RF sensor.

10. A method of controlling a plasma process parameter in processing a workpiece in a chamber of a plasma reactor, said method comprising:
providing a pair of RF power applicators disposed, respectively, at a ceiling and at a workpiece support of the plasma reactor;
placing a production workpiece in said chamber and applying RF power to one of said RF power applicators;
providing a ground return path through an impedance controller having a parallel impedance element and a series impedance element;
changing the impedances of said parallel and series impedance elements so as to move an input impedance of said impedance controller to a location in a two-dimensional complex impedance space at which a desired distribution of a plasma process parameter across a surface of said workpiece is realized.

11. The method of claim 10 wherein said plasma process parameter is a spatial distribution of a plasma process rate, said plasma process rate being one of an etch rate or a deposition rate.

12. The method of claim 10 further comprising finding said location by performing a search process prior to placing said production workpiece in said chamber, said search process comprising:
moving said input impedance to successive trial locations in said two-dimensional complex impedance space;
for each one of said successive trial locations, obtaining a measurement of said distribution of said plasma process parameter;
comparing each said measurement to said desired distribution to determine the measurement closest to said desired distribution, and selecting the corresponding location in said two-dimensional complex impedance space; and
setting the values of said variable parallel and series impedances so as to move said input impedance to said corresponding location.

13. The method of claim 12 wherein said obtaining a measurement comprise:
placing one of a succession of test workpieces in said chamber, and performing a plasma process; measuring one of etch depth distribution or deposition depth thickness distribution on said one test workpiece.

14. The method of claim 10 further comprising:
providing an RF sensor at one of said RF power applicators;
during processing of said production workpiece, detecting a change in an output of said RF sensor;
changing the impedances of said parallel and series impedance elements so as to reduce said change in the output of said RF sensor.

15. The method of claim 10 further comprising providing in said impedance controller:
a first terminal connected to the other one of said RF power applicators and a second terminal connected to ground, and a load impedance element;
connecting said series impedance element in series between said first terminal and said load impedance element, connecting said load impedance element in series between said series impedance element and said second terminal; and
connecting said parallel impedance element across one of (a) said first and second terminals, (b) said load impedance element.
